(19) United States
(12) Patent Application Publication
(10) Pub. No.: US 2007/0278657 A1
(43) Pub. Date: Dec. 6, 2007

(54) Chip stack, method of fabrication thereof, and semiconductor package having the same

(75) Inventor: Jong-Joo Lee, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/710,490

(22) Filed: Feb. 26, 2007

(30) Foreign Application Priority Data
May 30, 2006 (KR) 10-2006-0048876

(51) Int. Cl. H01L 23/485; H01L 21/50; H01L 23/52

(52) U.S. Cl. 257/692; 257/738; 257/777; 438/109; 257/E23.021; 257/E23.141; 257/E21.499

(57) ABSTRACT

A chip stack may include a first semiconductor chip and a second semiconductor chip stacked on the first semiconductor chip. Each semiconductor chip may have an active surface, a back surface opposite to the active surface, and a plurality of connection pads arranged in the center of the active surface. At least one through electrode may be formed in the first semiconductor chip and may be connected to at least one of the plurality of connection pads, and a portion of the at least one through electrode may be exposed by the back surface of the first semiconductor chip. The active surface of the first semiconductor chip may be arranged to face the active surface of the second semiconductor chip. The plurality of connection pads of the first semiconductor chip may be electrically connected to the plurality of connection pads of the second semiconductor chip.

### PRIORITY STATEMENT

This U.S. non-provisional application claims benefit of priority under 35 U.S.C. §119 of Korean Patent Application No. 2006-48876, filed on May 30, 2006 in the Korean Intellectual Property Office (KIPO), the entire contents of which are incorporated herein by reference.

### BACKGROUND

1. Field

Example embodiments relate to a semiconductor packaging technique, for example, to a chip stack, a method for manufacturing the chip stack and a semiconductor package having the chip stack.

2. Description of the Related Art

Memory products, for example DRAM's, may be manufactured with increased speed and capacity. One method for improving capacity is a chip stacking technique that may be used to stack semiconductor chips on a limited area of a package. A chip stack may increase the capacity of a product corresponding to the number of the semiconductor chips used in the chip stack.

FIG. 1 is a cross-sectional view of a conventional dual die semiconductor package 100.

Referring to FIG. 1, the package 100 may include a wiring substrate 40 having an upper surface 41 and a lower surface 42, a lower semiconductor chip 12 having chip pads 14, and an upper semiconductor chip 22 having chip pads 24. The lower semiconductor chip 12 may be mounted on the upper surface 41 of the wiring substrate 40. The upper semiconductor chip 22 may be stacked on the lower semiconductor chip 12 using a spacer 37. Bonding wires 35 may electrically connect the chip pads 14 and 24 of the semiconductor chips 12 and 22 to the wiring substrate 40. An encapsulant 50 may seal the semiconductor chips 12 and 22 and the bonding wires 35. External connection terminals 60, for example solder balls, may be formed on the lower surface 42 of the wiring substrate 40. The external connection terminals 60 may be electrically connected to the chip pads 14 and 24 of the semiconductor chips 12 and 22.

Signals input through the external connection terminals 60 may be transmitted to the chip pads 14 and 24 of the semiconductor chips 12 and 22 through the bonding wires 35. The semiconductor package 100 may be affected by a thermal problem during operation. To alleviate this problem, one of the semiconductor chips 12 and 22 may be operated, while the other may be on standby.

As a result, the bonding wires 35 connected to the standby semiconductor chip may act as stubs that may increase electrical load in the semiconductor package. Further, signals may be reflected from the standby semiconductor chip and may be input to the operating semiconductor chip, thereby causing noise in the operating semiconductor chip. The noise may reduce a channel of a semiconductor package and/or may reduce the valid window size of data at the system level. Accordingly, reduction of signal integrity may prevent the semiconductor package and/or the system from operating at higher speed.

### SUMMARY

Example embodiments may reduce the length of a stub in a semiconductor package, and thus may reduce electrical loading and improve signal integrity in the semiconductor package.

Example embodiments may allow a semiconductor package to operate at higher speed.

In an example embodiment, a chip stack may include a first semiconductor chip and a second semiconductor chip stacked on the first semiconductor chip. Each semiconductor chip may have an active surface, a back surface opposite to the active surface, and a plurality of connection pads arranged in the center of the active surface. At least one first through electrode may be formed in the first semiconductor chip and may be connected to at least one of the plurality of connection pads of the first semiconductor chip. A portion of the at least one first through electrode may be exposed from the back surface of the first semiconductor chip. The active surface of the first semiconductor chip may be arranged to face the active surface of the second semiconductor chip. The plurality of connection pads of the first semiconductor chip may be electrically connected to the plurality of connection pads of the second semiconductor chip.

According to an example embodiment, the plurality of connection pads of the first and second semiconductor chips may be arranged in the center of the active surface in a line.

According to an example embodiment, the plurality of connection pads of the first and second semiconductor chip are a plurality of chip pads.

According to an example embodiment, each of the first and second semiconductor chips include a plurality of chip pads formed on the active surface, and the plurality of connection pads of the first and second semiconductor chips may be a plurality of redistribution pads rerouted from the plurality of chip pads.

According to an example embodiment, the first through electrode may be formed through at least one of the plurality of connection pads of the first semiconductor chip.

According to an example embodiment, the plurality of connection pads of the first semiconductor chip may be electrically connected to the plurality of connection pads of the second semiconductor chip using conductive bumps.

According to an example embodiment, an adhesive layer may be interposed between the first semiconductor chip and the second semiconductor chip.

According to an example embodiment, a plurality of spacers may be arranged along the periphery between the first semiconductor chip and the second semiconductor chip.

According to an example embodiment, at least one spacer may connect a ground line or a power line of the first semiconductor chip to a ground line or a power line of the second semiconductor chip.

According to an example embodiment, a plurality of ball pads may be formed on the back surface of the first semiconductor chip having the at least one first through electrode, the plurality of ball pads may be connected to the exposed portion of the at least one first through electrode.

According to an example embodiment, a semiconductor package may include a chip stack having ball pads and solder balls formed on the ball pads.

According to an example embodiment, a plurality of second coupling pads may be connected to the plurality of chip pads of the second semiconductor chip and may extend to a peripheral region of the active surface of the second semiconductor chip. A plurality of first coupling pads may be formed on the active surface of the first semiconductor chip corresponding to the second coupling pad. A plurality of coupling bumps may electrically connect the plurality of first coupling pads to the plurality of second coupling pads. At least one second through electrode may extend through a peripheral region of the first semiconductor chip and may be connected to at least one of the plurality of first coupling pads. The at least one second through electrode may have a connection end exposed from the back surface of the first semiconductor chip.

According to an example embodiment, a plurality of first coupling pads may be connected to the plurality of connection pads of the first semiconductor chip and may extend to a peripheral region of the active surface of the first semiconductor chip. The at least one second through electrode may extend through a peripheral region of the first semiconductor chip and may be connected to at least one of the plurality of first coupling pads. The at least one second through electrode may have a connection end exposed from the back surface of the first semiconductor chip.

According to an example embodiment, a semiconductor package may include the chip stack according to an example embodiment. A wiring substrate may have an upper surface on which the chip stack may be mounted, and a lower surface. The wiring substrate may be electrically connected to the at least one first through electrode of the chip stack. A first encapsulant may seal the chip stack on the upper surface of the wiring substrate. External connection terminals may be formed on the lower surface of the wiring substrate and may be electrically connected to the exposed portion of the at least one first through electrode.

According to an example embodiment, at least one connection bump may be interposed between the exposed portion of the at least one first through electrode and the wiring substrate.

According to an example embodiment, the wiring substrate may have a central window, through which the portion of the first through electrode may be exposed. Bonding wires may electrically connect the wiring substrate to the exposed portion of the at least one first through electrode.

According to an example embodiment, a second encapsulant may seal the window of the lower surface of the wiring substrate.

In an example embodiment, a method for manufacturing a chip stack may include preparing a first wafer including a plurality of first semiconductor chips, each of the first semiconductor chips having an active surface with a plurality of first connection pads; preparing a second wafer including a plurality of second semiconductor chips, each of the second semiconductor chips having an active surface with a plurality of second connection pads corresponding to the first connection pads; forming at least one first through electrode, the at least one first through electrode being connected to at least one of the plurality of first connection pads and extending through the first wafer; stacking the second wafer on the first wafer so that the first connection pads may be electrically connected to the corresponding second connection pads; and dividing a stack of the first wafer and the second wafer into individual chip stacks.

According to an example embodiment, the method may further include backlapping the first wafer to expose a portion of the at least one first through electrode.

According to an example embodiment, the method may further include backlapping the second wafer before a dividing step and after a stacking step.

### BRIEF DESCRIPTION OF THE DRAWINGS

Example embodiments will be described with reference to the accompanying drawings.

FIG. 1 is a cross-sectional view of a conventional dual die package.

FIG. 2 is a cross-sectional view of a chip stack according to an example embodiment.

FIGS. 3A to 3C are cross-sectional views of a through electrode applicable to the chip stack of FIG. 2, according to example embodiments.

FIGS. 4 to 8 are cross-sectional views of a method for manufacturing the chip stack of FIG. 2, according to an example embodiment.

FIGS. 9 to 14 are cross-sectional views of a method for manufacturing the chip stack of FIG. 2, according to an example embodiment.

FIG. 15 is a cross-sectional view of a semiconductor package including the chip stack of FIG. 2, according to an example embodiment.

FIG. 16 is a cross-sectional view of a semiconductor package including the chip stack of FIG. 2, according to an example embodiment.

FIG. 17 is a cross-sectional view of a chip stack according to an example embodiment.

FIG. 18 is a cross-sectional view of a semiconductor package including the chip stack of FIG. 17, according to an example embodiment.

FIG. 19 is a cross-sectional view of a chip stack according to an example embodiment.

FIG. 20 is a cross-sectional view of a chip stack according to an example embodiment.

FIG. 21 is a cross-sectional view of a chip stack according to an example embodiment.

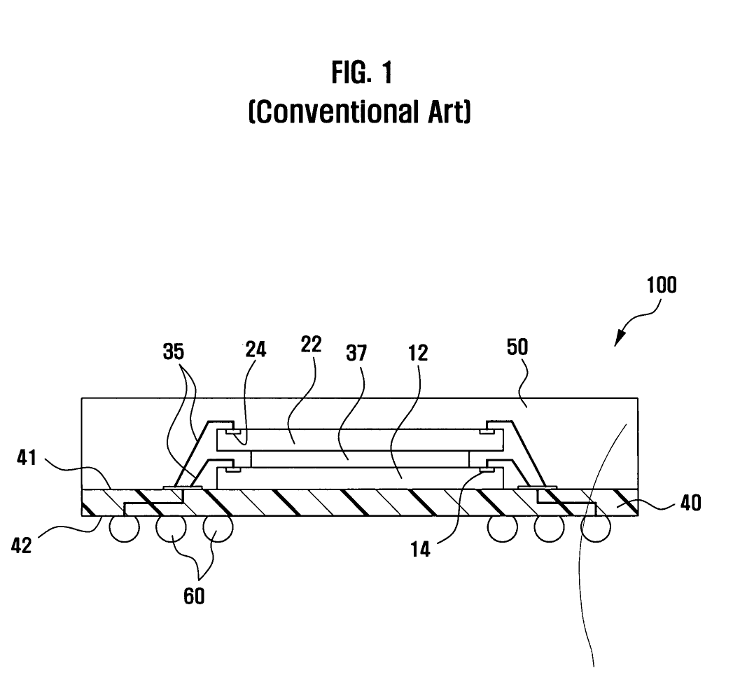

### DESCRIPTION OF EXAMPLE EMBODIMENTS

Example embodiments are described more fully hereinafter with reference to the accompanying drawings. Example embodiments may, however, be embodied in many different forms and should not be construed as limited to the example embodiments set forth herein. Rather, the disclosed embodiments are provided so that this disclosure will be thorough and complete, and will fully convey the scope of the example embodiments to those skilled in the art. The principles and features of the example embodiments may be employed in varied and numerous embodiments without departing from the scope.

It should be noted that the figures are intended to illustrate the general characteristics of methods and devices of example embodiments, for the purpose of the description of example embodiments herein. These drawings are not, however, to scale and may not precisely reflect the characteristics of any given embodiment, and should not be interpreted as defining or limiting the range of values or properties of example embodiments within the scope. Rather, for simplicity and clarity of illustration, the dimensions of some of the elements are exaggerated relative to other elements.

Further, well-known structures and processes are not described or illustrated in detail to avoid obscuring example embodiments. Like reference numerals are used for like and corresponding parts of the various drawings.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

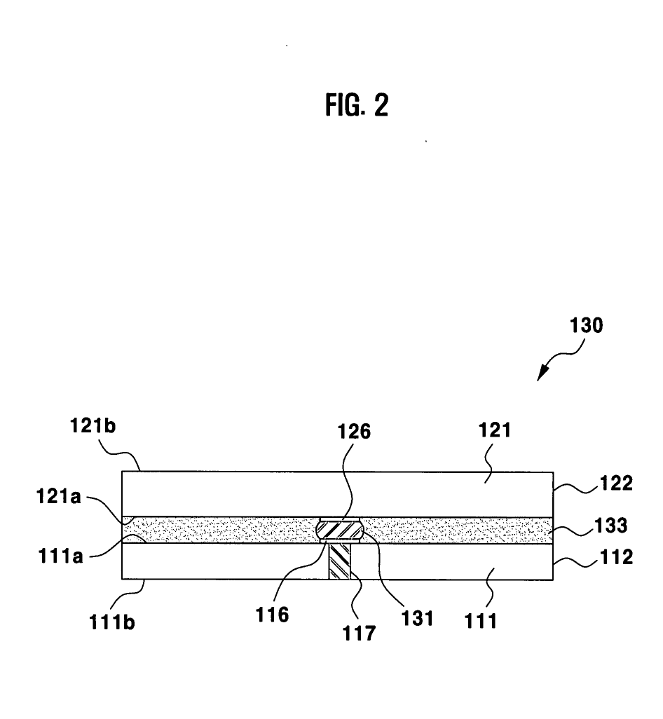

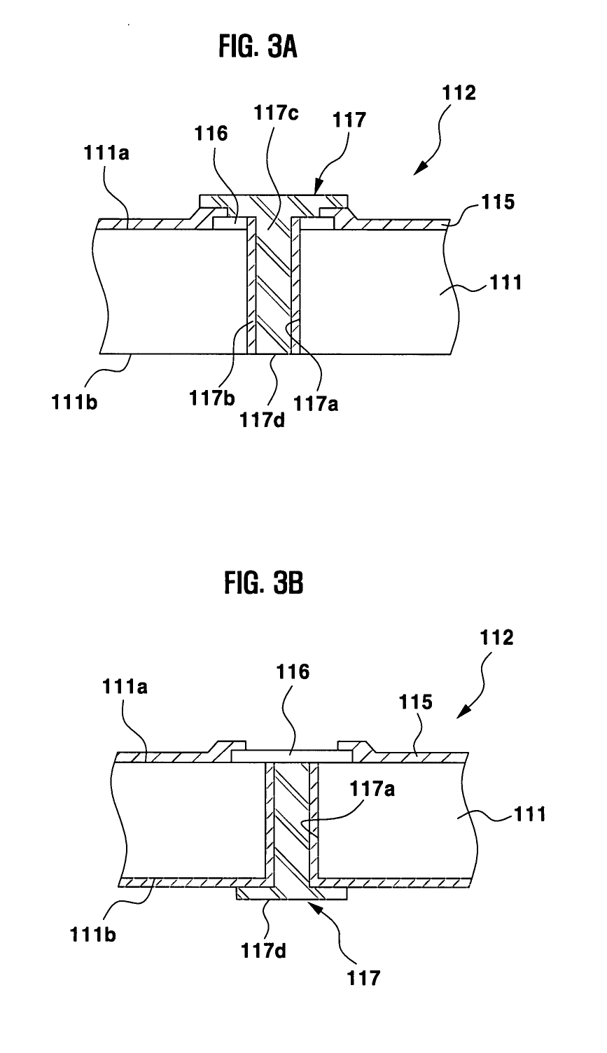

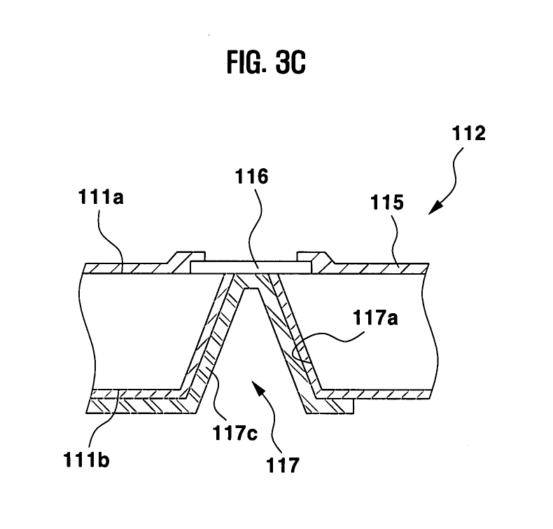

FIG. 2 is a cross-sectional view of a chip stack 130 according to an example embodiment. FIG. 3A is a cross-sectional view of a through electrode 117, according to an example embodiment, applicable to the chip stack 130 of FIG. 2.

Referring to FIGS. 2 and 3A, the chip stack 130 may include a lower semiconductor chip (hereinafter referred to as a first chip) 112 and an upper semiconductor chip (hereinafter referred to as a second chip) 122. The first chip 112 may have an active surface 111a having first connection pads 116 and a back surface 111b. The second chip 122 may have an active surface 121a having second connection pads 126 and a back surface 121b. The second chip 122 may be mounted on the first chip 112 such that the active surface 121a of the second chip 122 may face the active surface 111a of the first chip 112. Conductive bumps 131, for example, solder bumps, Au bumps or Ni bumps, may electrically connect the first connection pads 116 to the second connection pads 126. An adhesive layer 133 may be interposed between the first chip 112 and the second chip 122. At least one of the first and second chips 112 and 122, for example, the first chip 112, may have through electrodes 117 connected to the first connection pads 116. The through electrode 117 may connect the chip stack 130 to external connection terminals.

In the chip stack 130, the conductive bumps 131 may serve as stubs. The length of the stub may correspond to the height of the conductive bump 131. The use of conductive bumps in a chip stack 130 may reduce the length of the stubs, thus the electrical load of a semiconductor package having the chip stack 130 may be reduced and the signal integrity may be improved. Accordingly, a semiconductor package may operate at higher speed.

A more detailed description of the chip stack 130 follows below. Because the second chip 122 is similar to the first chip 112, the description of the chip structure is based on the first chip 112.

The first chip 112 may include a silicon substrate 111 having an active surface 111a and a back surface 111b opposite to the active surface 111a. The first connection pads 116 may be arranged in the center of the active surface 111a. A passivation layer 115 may cover the active surface 111a, but may expose the first connection pads 116. Integrated circuits (not shown) may be formed in the silicon substrate 111. The first connection pads 116 may be electrically connected to the integrated circuits. For example, the first connection pads 116 may be formed from materials having good electrical conductivity, for example, Al or Cu. For example, the passivation layer 115 may be formed from oxide, nitride or alloy thereof. The passivation layer 115 may protect the integrated circuits from the external environment.

The first connection pads 116 may be arranged in the center of the active surface 111a in a line, so that the second chip 122 may be aligned with the first chip 112. The first connection pads 116 may be chip pads formed on the active surface 111a, or redistribution pads rerouted from chip pads. For example, if the first connection pads 116 are chip pads, the chip pads 116 may be arranged in the center of the active surface 111a in a line. For example, if the first connection pads 116 are redistribution pads, chip pads (not shown) may be provided in arrangements other than a linear arrangement on the active surface 111a and may be rerouted to the first connection pads 116 that may be arranged in the center of the active surface 111a in a line. The conductive bumps 131 may connect the first connection pads 116 of the first chip 112 to the second connection pads 126 of the second chip 122. For example, the conductive bumps 131 may be solder bumps, Au bumps or Ni bumps. The face-to-face stack of the first chip 112 and second chip 122 may reduce the distance between the first connection pad 116 and the second connection pad 126.

The first chip 112 may have a thickness that may be smaller than the thickness of the second chip 122, so that the length of the through electrode 117 may be reduced. For example, if the chip stack 130 is fabricated at wafer level, a second wafer may be stacked on the first wafer and the first wafer, that may include a first chip, may be backlapped. Thus, the thickness of the first chip 112 may be reduced.

The adhesive layer 133 may be interposed between the first chip 112 and the second chip 122. The adhesive layer 133 may attach the second chip 122 to the first chip 112 and protect the conductive bump 131 from the external environment. For example, the adhesive layer 133 may be a dielectric epoxy or a silicone based adhesive.

Although a conductive bump 131 may electrically connect the first chip 112 and the second chip 122, example embodiments may not be limited in this regard. For example, the conductive bump 131 may be replaced with an anisotropic conductive film (ACF). The ACF may also replace the adhesive layer 133.

The through electrode 117 may extend through the first chip 112. The through electrode 117 may be formed through the first connection pad 116. The through electrode 117 may be formed of conductive material 117c provided in a through hole 117a. The through electrode 117 may have a connection end 117d exposed from the back surface 111b of the first chip 112. An insulating layer 117b may be interposed between the through hole 117a and the conductive material 117c. The insulating layer 117b may serve as an insulator between the conductive material 117c and the silicon substrate 111. The internal diameter of the through hole 117a may be uniform.

Although the through electrode 117 may be formed through the first connection pad 116, the through electrode 117 may be not limited in this regard. FIGS. 3B and 3C are cross sectional views of the through electrode 117 according to example embodiments. For example, the through electrode 117 may be formed without penetrating the first connection pad 116 so that a back surface of the first connection pad 116 may be exposed. Referring to FIG. 3B, the through electrode 117 may be formed by filling the through hole 117a with the conductive material 117c. Referring to FIG. 3C, the through electrode 117 may be formed by coating the conductive material 117c on inner walls of the through hole 117a. The internal diameter of the through hole 117a may be uniform as shown in FIG. 3B or the diameter may be reduced upwards from the back surface 111b to the active surface 111a of the first chip 112 as shown in FIG. 3C.

Spacers (not shown) may be interposed between the first chip 112 and the second chip 122. The spacer may provide for stable stacking of the second chip 122 on the first chip 112. The height of the spacer may correspond to the height of the conductive bump 131. The spacer may be arranged regularly along the periphery between the first chip 112 and the second chip 122.

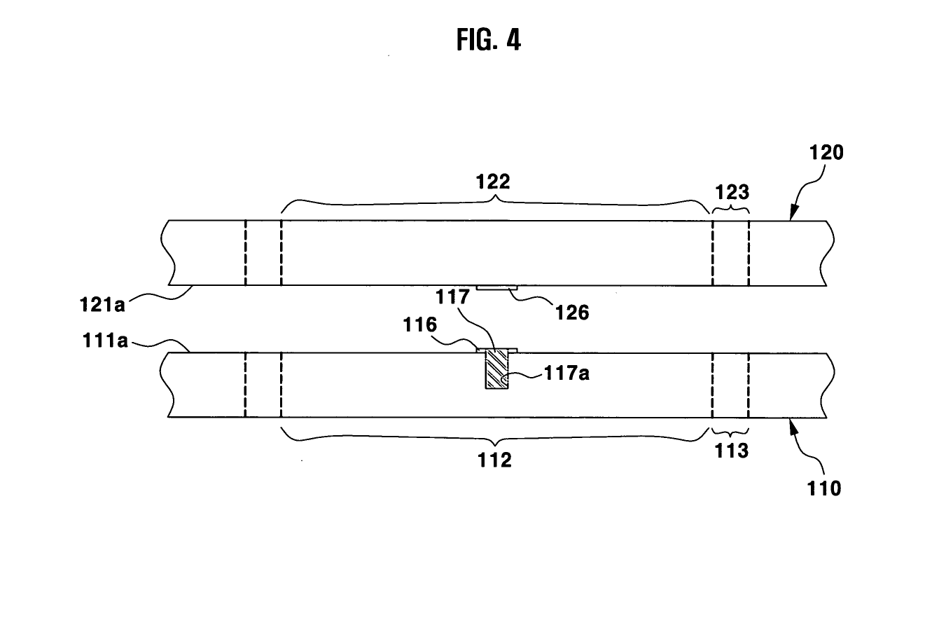

FIGS. 4 to 8 are cross-sectional views of a method for manufacturing the chip stack 130 of FIG. 2, according to an example embodiment.

Referring to FIG. 4, a first wafer 110 and a second wafer 120 may be prepared. The first wafer 110 may have an active surface 111a and a back surface 111b opposite to the active surface 111a. The first wafer 110 may include a plurality of first chips 112. The first wafer 11 may have first scribe lanes 113 between the adjacent first chips 112. The first chip 112 may have first connection pads 116 arranged in the center of the active surface 111a. Through electrodes 117 may be formed to extend through the first chip 112 to a predetermined or desired depth. For example, through holes 117a for the through electrodes 117 may be formed using a drilling method or an etching method.

The second wafer 120 may have an active surface 121a and a back surface 121b opposite to the active surface 121a. The second wafer 120 may include a plurality of second chips 122 corresponding to the plurality of first chips 112. The second wafer may have second scribe lanes 123 between the adjacent second chips 122. Each of the second chips 122 may have second connection pads 126 arranged in the center of the active surface 121a.

The first wafer 110 may have the same structure as the second wafer 120, except the second wafer 120 may not have a through electrode 117.

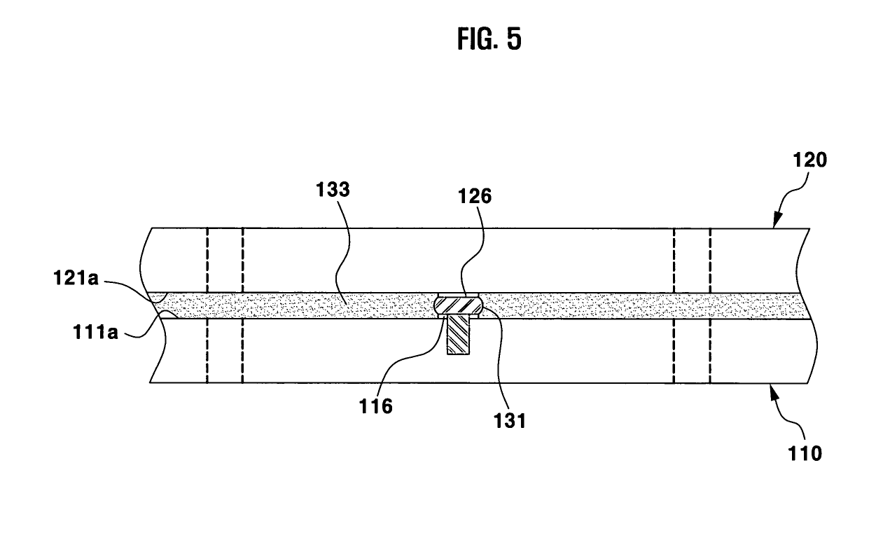

Referring to FIG. 5, the second wafer 120 may be stacked on the first wafer 110. The active surface 111a of the first wafer 110 may face the active surface 121a of the second wafer 120. Conductive bumps 131 may connect the first connection pads 116 to the second connection pads 126. An adhesive layer 133 may be interposed between the first wafer 110 and the second wafer 120. The second chips 122 may be aligned with the first chips 112.

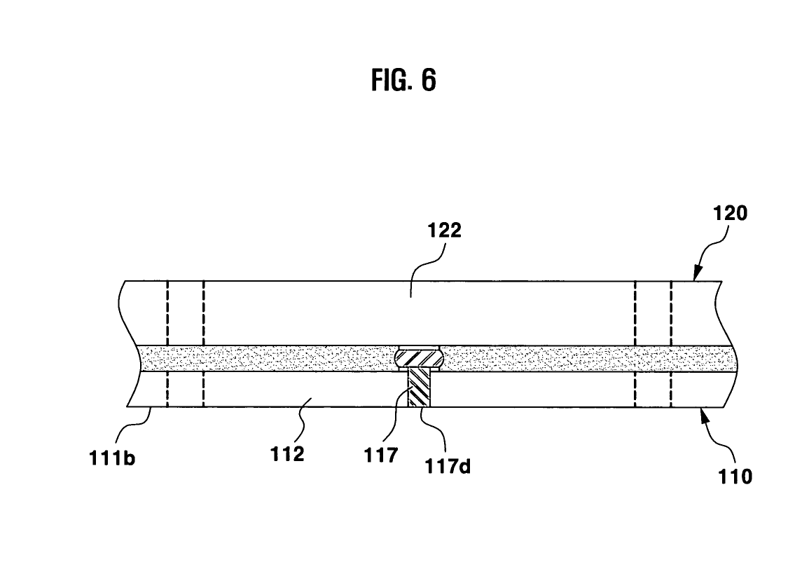

Referring to FIGS. 6 and 3A, the back surface 111b of the first wafer 110 may be backlapped. After a backlapping process, the back surface 111b may expose a portion 117d of the through electrode 117. The exposed portion 117d of the through electrode 117 may be hereinafter referred to as a connection end 117d. For example, the backlapping process may be a grinding method, an etching method or a chemical mechanical polishing method.

The second wafer 120 may be stacked on the first wafer 110. The second wafer 120 may serve as a support plate for supporting the first wafer 110 during the backlapping process performed on the back surface of 111b of the first wafer 110. Compared with a backlapping process that does not include support for a first wafer 110, the backlapping process performed according to example embodiments in FIGS. 6 and 3A may be more effective in reducing the thickness of a first wafer 110. The backlapping process may reduce the height of the through electrode 117. Thus, the length of signal transmission to the second chip 122 via the through electrode 117 may be reduced. Furthermore, a thinner chip stack may be fabricated.

For example, the thickness of the first wafer 110 initially may be about 700 μm, and after a backlapping process the thickness of the first wafer 110 may be about 100 μm or less. The height of the through electrode 117 may be about 100 μm. The connection end 117d of the through electrode 117 may be exposed from the back surface 111b of the first wafer 110.

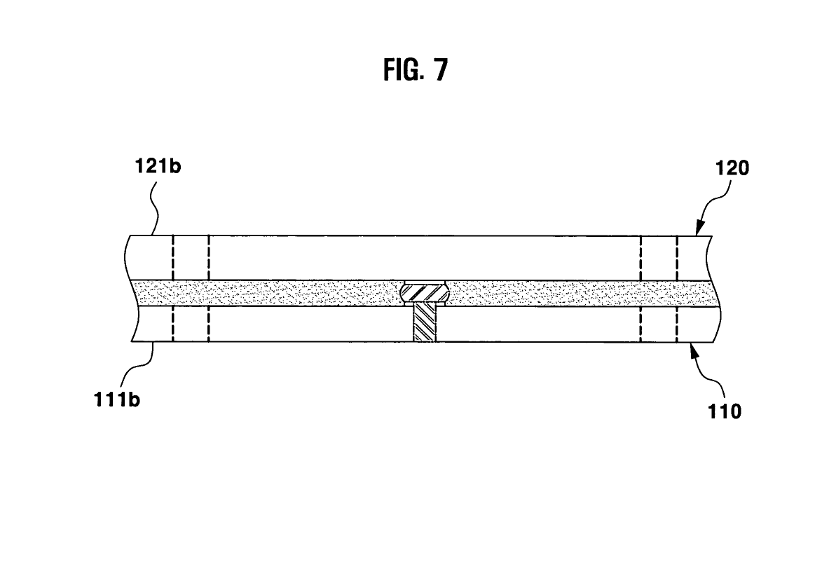

Referring to FIG. 7, the back surface 121b of the second wafer 120 may be backlapped. A backlapping process may implement the same method as the backlapping process for backlapping the first wafer 110.

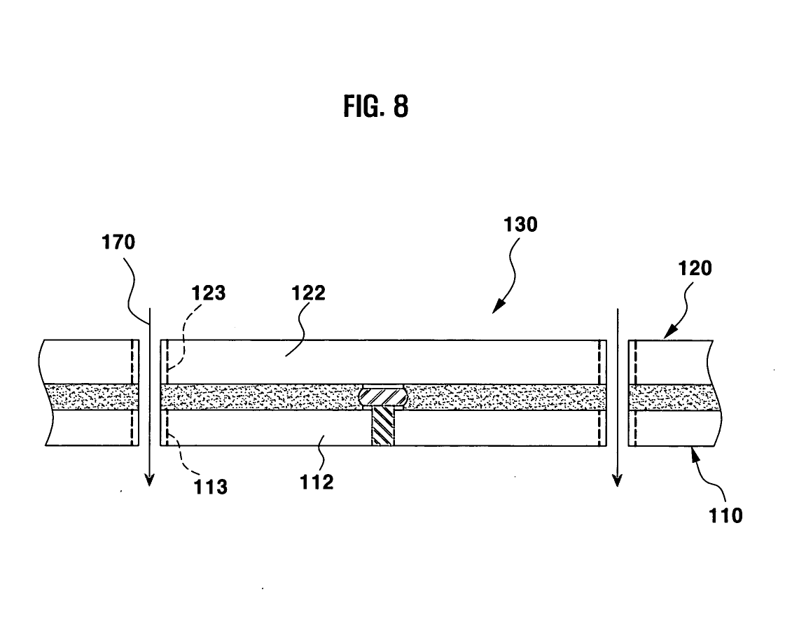

Referring to FIG. 8, a stack of the first wafer 110 and the second wafer 120 may be divided into individual chip stacks 130. The stack of the first wafer 110 and the second wafer 120 may be separated along the scribe lanes 113 and 123, for example, using a sawing blade 170.

Because the first scribe lanes 113 correspond to the second scribe lanes 123, the sawing blade 170 may saw the stack of the first wafer 110 and the second wafer 120 in a single operation.

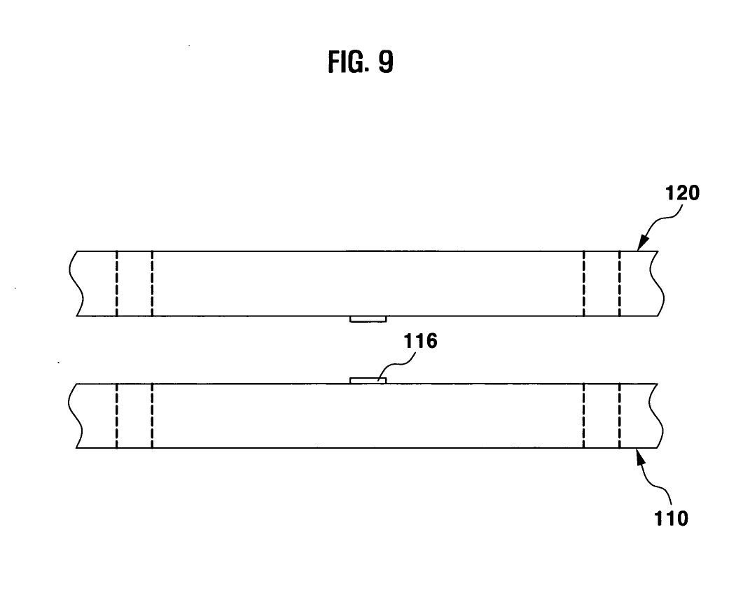

FIGS. 9 to 14 are cross-sectional views of a method for manufacturing the chip stack 130 of FIG. 2, according to an example embodiment.

The method of this example embodiment may proceed in the same manner as the method of FIGS. 4 to 8, except that through electrodes 117 may be formed after a backlapping process of a first wafer 110. The repeated description is herein omitted.

Referring to FIG. 9, a first wafer 110 and a second wafer 120 may be prepared. Through electrodes may not have been formed in the first wafer 110.

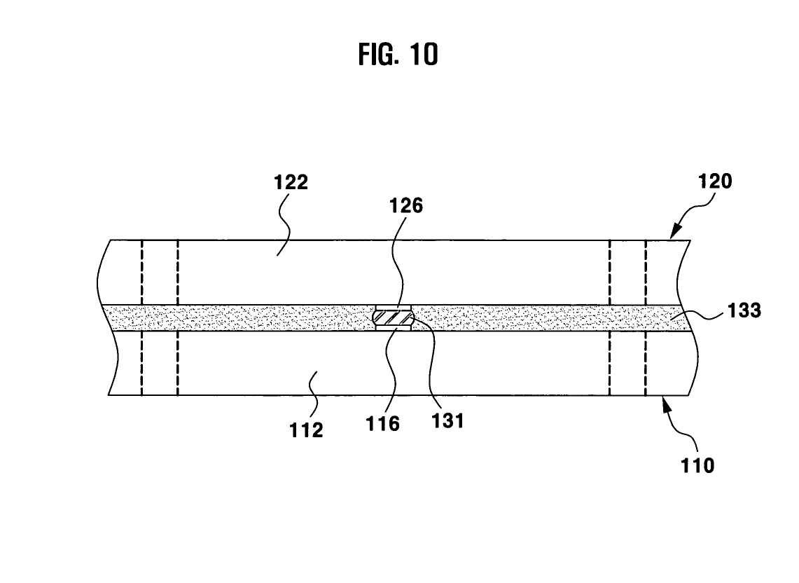

Referring to FIG. 10, the second wafer 120 may be stacked on the first wafer 110. Conductive bumps 131 may electrically connect first connection pads 116 to second connection pads 126. An adhesive layer 133 may be interposed between the first wafer 110 and the second wafer 120. Second chips 122 may be aligned with first chips 112.

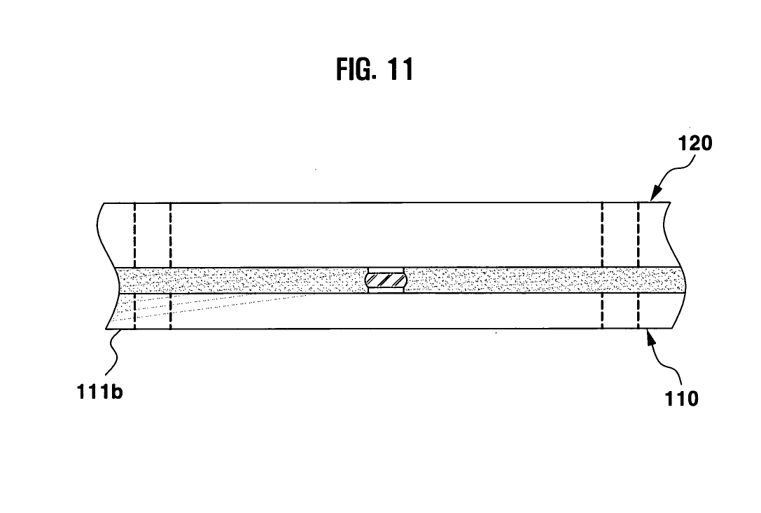

Referring to FIG. 11, a back surface 111b of the first wafer 110 may be backlapped.

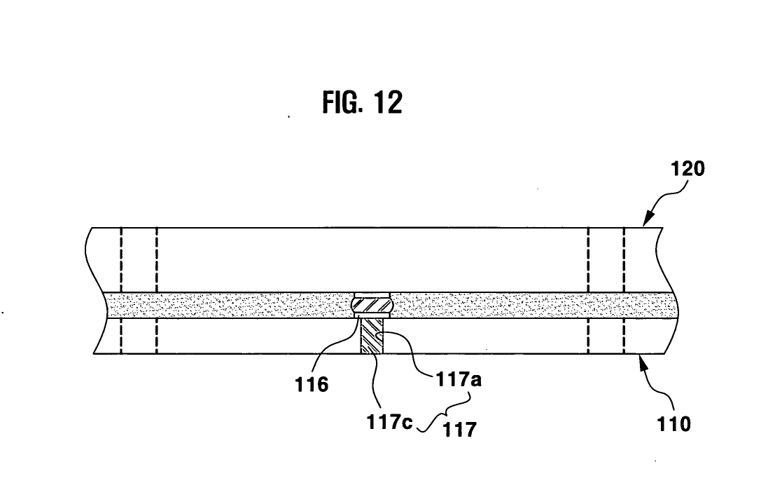

Referring to FIG. 12, a through electrode 117 may be formed in the first wafer 110. Conductive material 117c may be filled in a through hole 117a to form the through electrode 117. The through hole 117a may extend through the first wafer 110, so that a back surface of the first connection pad 116 may be exposed from the back surface 111b of the first wafer 110. For example, the through electrode 117 may be formed according to an example embodiment as shown in FIG. 3B or according to the example embodiment as shown in FIG. 3C.

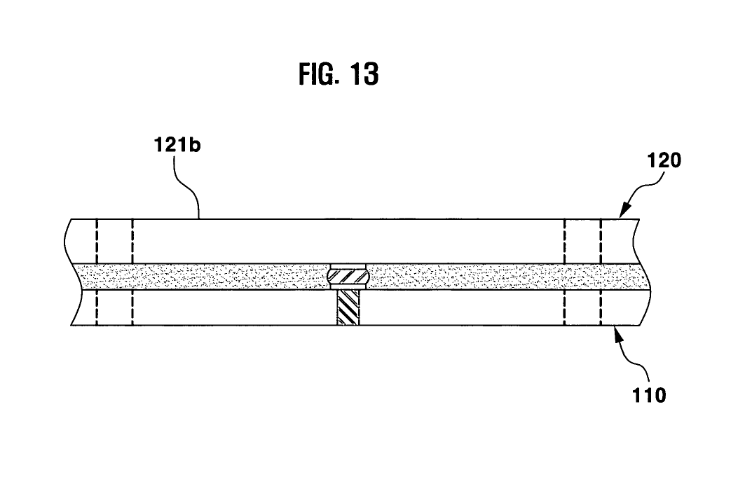

Referring to FIG. 13, a back surface 121b of the second wafer 120 may be backlapped.

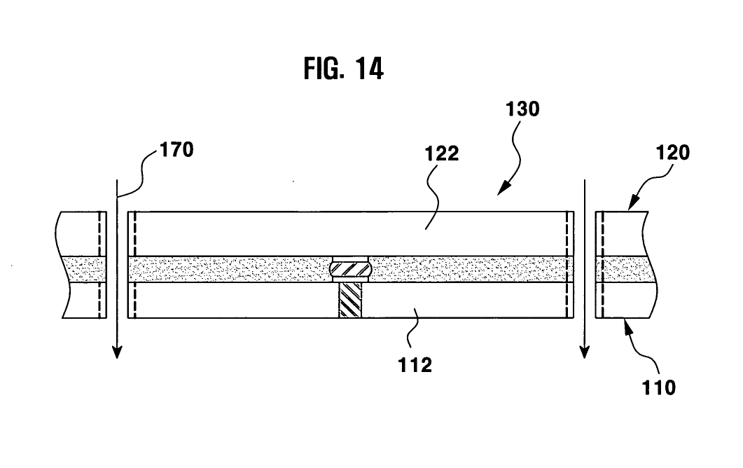

Referring to FIG. 14, the stack of the first wafer 110 and the second wafer 120 may be divided into individual chip stacks 130, for example, using a sawing blade 170.

According to an example embodiment, a chip stack 130 may be fabricated at chip level. For example, a first wafer 110 having through electrodes 117 may be prepared, each through electrode 117 having a connection end 117c exposed from a back surface 111b. A second wafer 1120 having a backlapped back surface 121b may be prepared. The first wafer 110 may be divided into individual first chips 112 and the second wafer 120 may be divided into individual second chips 122. A second chip 122 may be stacked on a first chip 112 such that an active surface 111a of the first chip 112 may face an active surface 111b of the second chip 122. First connection pads 116 may be electrically connected to second connection pads 126 using conductive bumps 131. An adhesive layer 133 may be interposed between the first chip 112 and the second chip 122.

According to example embodiments, individual second chips 122 may be stacked on a first wafer 110; individual first chips 112 may be stacked on a second wafer 120; or a first chip 112 may be mounted on a wiring substrate 140 and a second chip 122 may be stacked on the first chip 112.

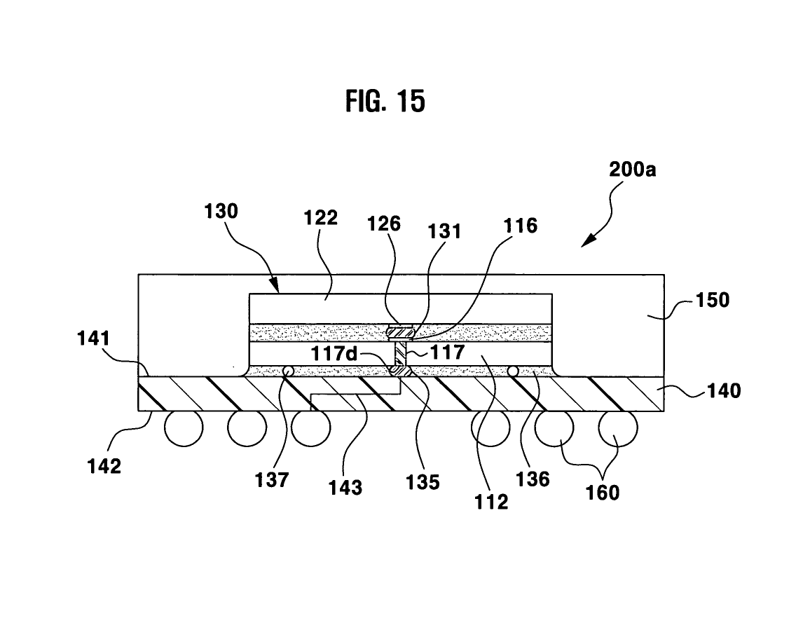

FIG. 15 is a cross-sectional view of an example of a semiconductor package 200a having the chip stack 130 of FIG. 2.

Referring to FIG. 15, the semiconductor package 200a may be a ball grid array (BGA) semiconductor package. The ball grid array semiconductor package 200a may include a wiring substrate 140. Connection bumps 135 may be formed on an upper surface 141 of the wiring substrate 140. External connection terminals 160 may be formed on a lower surface 142 of the wiring substrate 140. The chip stack 130 may be mounted on the upper surface 141 of the wiring substrate 140 using the connection bump 135.

The connection end 117d of the through electrode 117 of the chip stack 130 may be bonded to the upper surface 141 of the wiring substrate 140 via the connection bump 135. For example, the chip stack 130 may be mounted on the upper surface 141 of the wiring substrate 140 using a flip chip bonding method. A filling layer 136 may be interposed between the chip stack 130 and the wiring substrate 140 to protect the conductive bump 135 from the external environment. For example, the connection bump 135 may be a solder bump, Au bump or Ni bump. For example, the filling layer 136 may be formed using an underfill process. Spacers 137 may be arranged along the periphery between the chip stack 130 and the upper surface 141 of the wiring substrate 140. The use of the spacer 137 may allow for stable mounting of the chip stack 130 on the wiring substrate 140. The diameter of the spacer 137 may correspond to the height of the connection bump 135.

For example, the wiring substrate 140 may be a printed circuit board, a tape wiring substrate, a ceramic wiring substrate, a silicon wiring substrate, or a lead frame.

An encapsulant 150 may seal the upper surface 141 of the wiring substrate 140 to protect the chip stack 130 from the external environment.

The external connection terminals 160 may be provided on the lower surface 142 of the wiring substrate 140. An inner wiring 143 of the wiring substrate 140 may electrically connect the external connection terminal 160 to the connection bump 135. The external connection terminals 160 may include solder balls.

A first connection pad 116 may be electrically connected to a second connection pad 126 using a conductive bump 131 and the through electrode 117 located on the first connection pad 116 may be electrically connected to the external connection terminal 160. Thus, an input signal may be input to the first connection pad 116 via the external connection terminal 160 and to the second connection pad 126 via the conductive bump 131. The conductive bump 131 may serve as a stub for the chip stack 130. Because the length of the stub corresponds to the height of the conductive bump 131, a length of the stub may be reduced. Thus, the electrical load of the semiconductor package 200a may be reduced and signal integrity may be improved. Accordingly, the semiconductor package 200a may operate at higher speed.

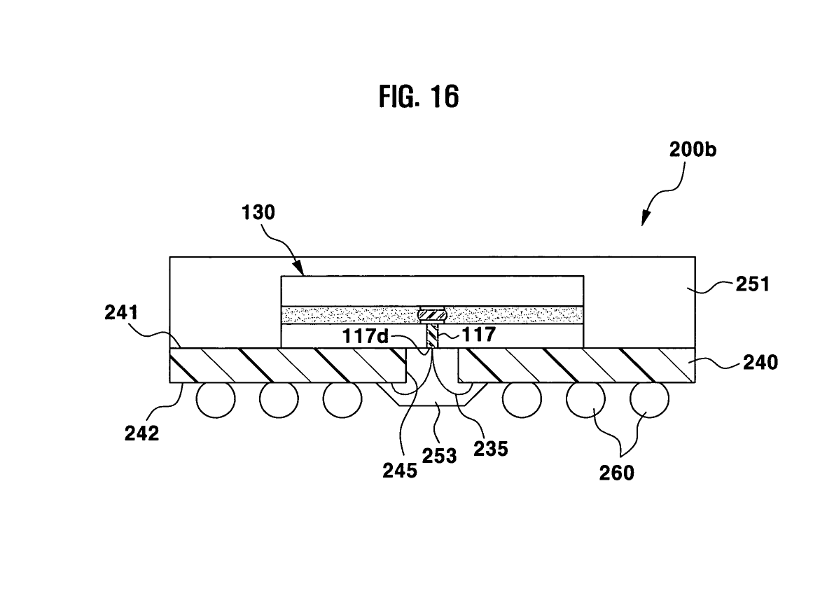

FIG. 16 is a cross-sectional view of a semiconductor package 200b including the chip stack 130 of FIG. 2, according to an example embodiment. The chip stack 130 may be connected to external connection terminals 260 using bonding wires 235.

Referring to FIG. 16, a semiconductor package 200b may be a board on chip (BOC) semiconductor package. The BOC semiconductor package 200b may include a wiring substrate 240 having an upper surface 241 and a lower surface 242. The wiring substrate 240 may have a central window 245.

The chip stack 130 may be mounted on the upper surface 241 of the wiring substrate 240 such that a connection end 117d of a through electrode 117 of the chip stack 130 may be exposed through the central window 245 of the wiring substrate 240.

The bonding wires 235 may electrically connect the connection end 117d of the through electrode 117 to the wiring substrate 240 through the central window 245.

Encapsulant 251 and 253 may seal the chip stack 130 and the bonding wires 235 to protect them from the external environment. The encapsulant 251 and 253 may include a first encapsulant 251 for the chip stack 130 and a second encapsulant 253 for the bonding wires 235. The first encapsulant 251 may be formed simultaneously with or separately from the second encapsulant 253.

External connection terminals 260 may be provided on the lower surface 242 of the wiring substrate 240, clear of the second encapsulant 253. The external connection terminals 260 may be electrically connected to the through electrode 117 via the wiring substrate 240 and/or the bonding wires 235. The height of the external connection terminal 260 may be greater than the height of the second encapsulant 253 above the back surface 242 of the wiring substrate 240, so that the semiconductor package 200b may be mounted on a mother board. For example, the external connection terminals 260 may be solder bumps.

According to an example embodiment, the semiconductor package 200b may be a lead on chip (LOC) semiconductor package in which a lead frame is used as a wiring substrate.

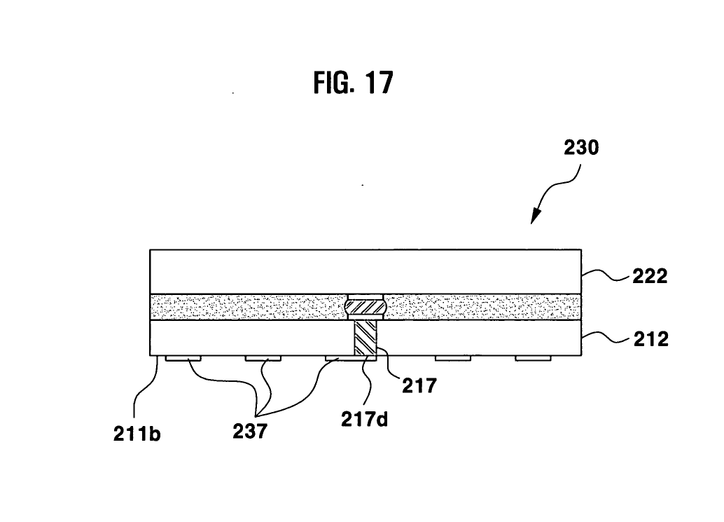

FIG. 17 is a cross-sectional view of a chip stack 230 according to an example embodiment.

Referring to FIG. 17, a chip stack 230 may be the same as the chip stack 130 of FIG. 2 except ball pads 237 may be provided on a lower surface 211b of a first chip 212 and may be connected to connection ends 217d of through electrodes 217. For example, the ball pads 237 may be formed using a rerouting process. Although not shown, a passivation layer may cover the back surface 211b of the first chip 212 but may expose the ball pads 237.

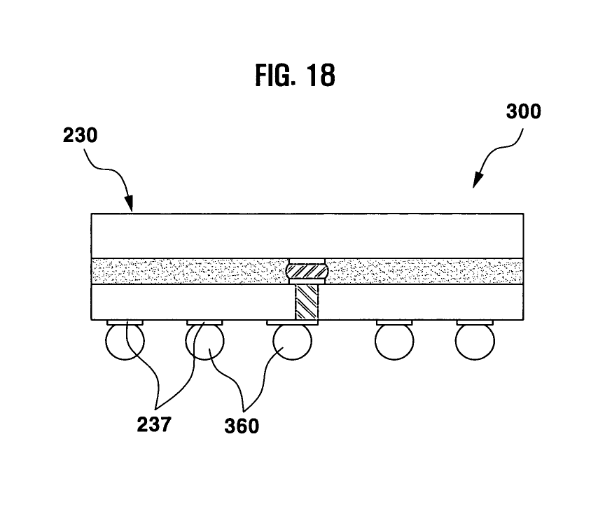

FIG. 18 is a cross-sectional view of a semiconductor package 300 having the chip stack 230 of FIG. 17, according to an example embodiment.

Referring to FIG. 18, the semiconductor package 300 may have external connection terminals 360 formed on ball pads 237. For example, the external connection terminals 360 may be solder balls.

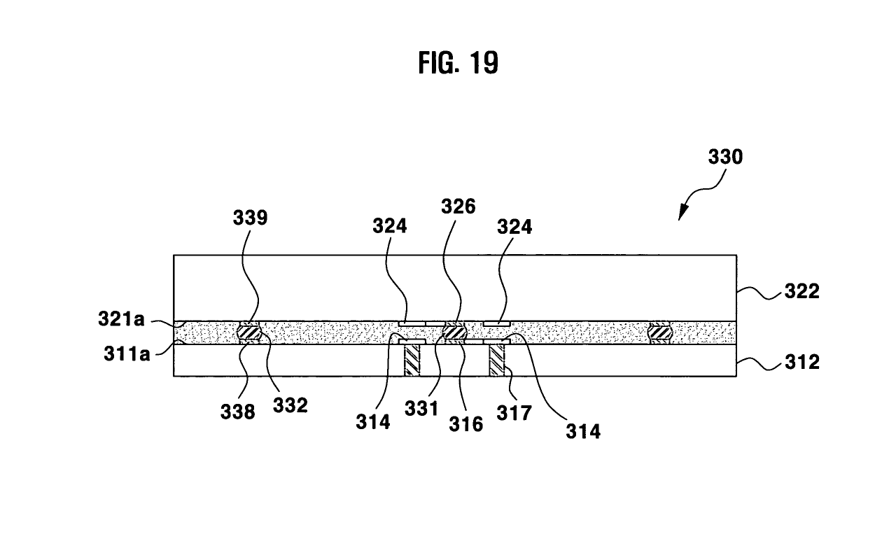

Although the example embodiments show chip pads used as connection pads, chip pads may be distinct from connection pads, as shown in chip stacks according to example embodiments of FIGS. 19 to 21. For example, the connection pads may be rerouted from the chip pads and be arranged in the center of an active surface in a line.

Referring to FIG. 19, a chip stack 330 may include a first chip 312 having first chip pads 314 and a second chip 322 having second chip pads 324. The first chip pads 314 and the second chip pads 324 may be arranged in the central portions of active surfaces 311a and 321a of the first chip 312 and the second chip 322, respectively. For example, the first chip pads 314 and second chip pads 324 may be arranged in two rows in the central portions of active surfaces 311a and 321a of the first chip 312 and the second chip 322, respectively. Spacers 332 may be interposed between the first chip 312 and the second chip 322.

The detailed description of the chip structure is based on the first chip 312. The first chip 312 may have an active surface 311a. The first chip pads 314 may be arranged in the central portion of the active surface 311a. For example, the first chip pads 314 may be arranged in two rows at regular intervals. Through electrodes 317 may extend through the first chip 312 and be connected to the first chip pads 314.

If the first chip pads 314 and the second chip pads 324 have a two-row arrangement, the first chip pads 314 may be not electrically connected to the corresponding second chip pads 324. Therefore, connection pads may be formed to connect the first chip pads 314 to the second chip pads 324. First connection pads 316 may be arranged between the adjacent first chip pads 314 and be connected to the first chip pads 314. For example, the first connection pad 316 may be formed by rerouting the first chip pad 314.

Because the first connection pad 316 may be formed between the adjacent first chip pads 314, the size of the first connection pad 316 may be smaller than the size of the first chip pad 314. As a result, the size of a conductive bump 331 may be reduced and thus the length of a stub may be reduced.

The spacers 332 may be arranged along the periphery between the first chip 312 and the second chip 322. For example, the spacers 332 may be dielectric balls of plastic or metal balls. The example embodiment in FIG. 19 shows the spacers 332 as metal balls. Each spacer 332 may be joined to a first spacer pad 338 of the first chip 312 and a second spacer pad 339 of the second chip 322.

Although this example embodiment shows the spacer 332 as a support for stacking the second chip 322 on the first chip 312, the spacer 332 may be not limited in this regard. For example, at least one spacer 332 may be used to connect a ground line or a power line of the first chip 312 to a ground line or a power line of the second chip 322. Thus, a stable power line and a ground line may be incorporated and a parallel network may be formed to reduce noise of the power and/or ground lines of the first chip 312 and the second chip 322. The first spacer pad 338 and the second spacer pad 339 may be connected to a ground line or a power line of the first chip 312 and the second chip 322, respectively, or to the chip pad 314 or the chip pad 324 for ground or power of the first chip 312 and the second chip 322, respectively. The first spacer pads 338 and the second spacer pads 339 for ground or power lines may be symmetrically arranged with regard to the first connection pad 316 and the second connection pad 326, respectively, such that the first spacer pad 338 may be connected to the corresponding second spacer pad 339 through the spacer 332.

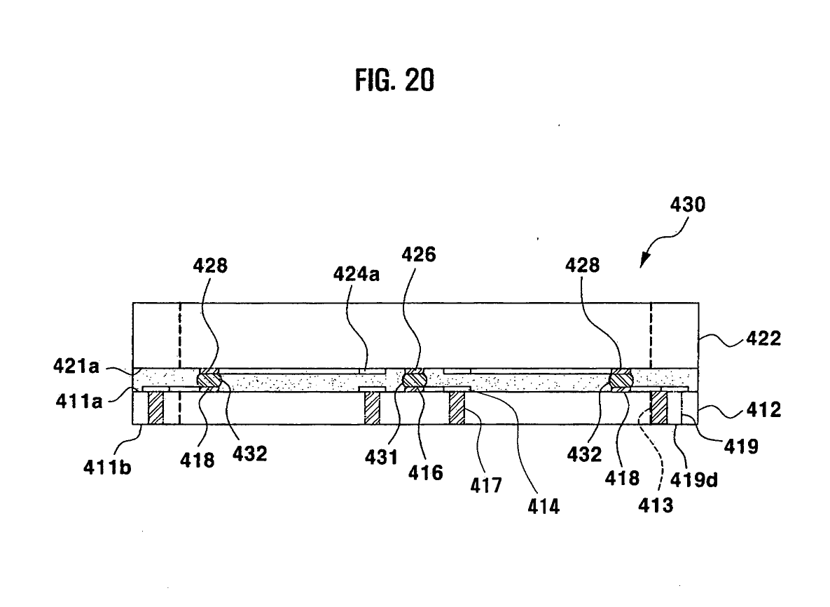

FIG. 20 is a cross-sectional view of a chip stack 430 according to an example embodiment.

Referring to FIG. 20, the chip stack 430 may include a first chip 412 and a second chip 422 stacked on the first chip 412. The second chip 422 may have an active surface 421a with a second connection pad 426, at least one second chip pad 424a and a second coupling pad 428. The second chip pad 424a (hereinafter referred to as a second non-connection chip pad) may not be connected to the second connection pad 426. The second coupling pad 428 may be formed in a peripheral region of the active surface 421a and may be connected to the second non-connection chip pad 424a. For example, the second coupling pad 428 and the second connection pad 426 may be formed using a rerouting process.

The first chip 412 may have an active surface 411a with a first connection pad 416 and a first coupling pad 418, and a back surface 411b opposite to the active surface 411a. The first coupling pad 418 may be formed on the active surface 411a corresponding to the second coupling pad 428 of the second chip 422. For example, the first connection pad 416 and the first coupling pad 418 may be formed using a rerouting process. The first chip 412 may have first through electrodes 417 and second through electrodes 419. Because the first through electrodes 417 are the same as those in the above embodiments, the detailed description is omitted. The second through electrode 419 may extend through a peripheral region of the first chip 412 and be connected to the first coupling pad 418. The second through electrode 419 may have a connection end 419d exposed from the back surface 411b of the first chip 412. The first chip 412 may include scribe lanes 413, and the second through electrodes 419 may be arranged in the scribe lanes 413.

Conductive bumps 431 may connect the first connection pad 416 to the second connection pad 426. Coupling bumps 432 may connect the first coupling pad 418 to the second coupling pad 428. For example, the coupling bump 432 may be the same as the conductive bump 431.

In this manner, the second non-connection chip pad 424a connected to the second coupling pad 428 may be connected externally via the coupling bump 432, the first coupling pad 418 and/or the second through electrode 419.

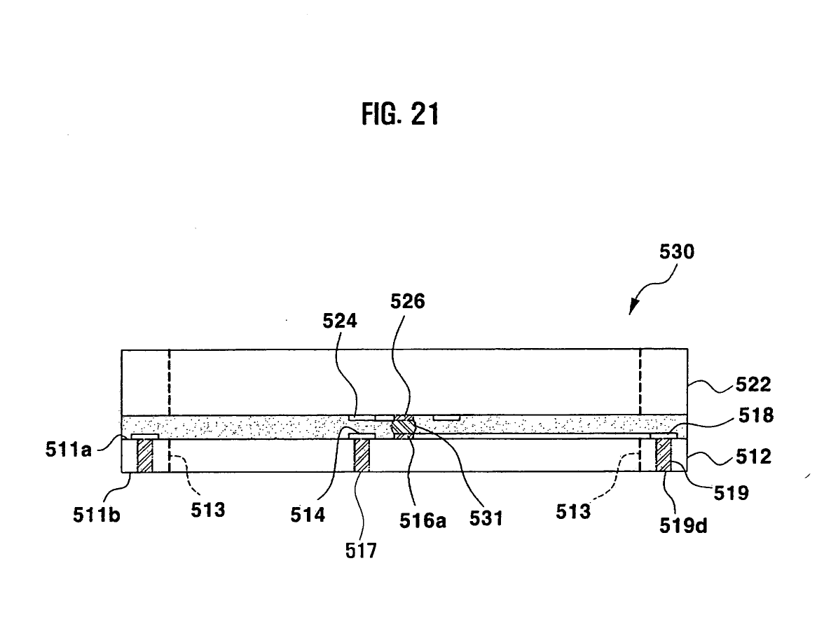

FIG. 21 is a cross-sectional view of a chip stack 530 according to an example embodiment.

Referring to FIG. 21, the chip stack 530 may include a first chip 512 and a second chip 522. The first chip 512 may have an active surface 511a with a first chip pad 514, at least one first connection pad 516a and a first coupling pad 518, and a back surface 511b. The first connection pad 516a (hereinafter referred to as a first dummy connection pad) may not be connected to the first chip pad 514. The first coupling pad 518 may be formed in a peripheral region of the active surface 511a, and be connected to the first dummy connection pad 516a. The first chip 512 may have first through electrodes 517 and second through electrodes 519. The second through electrode 519 may extend through a peripheral region of the first chip 512 and be connected to the first coupling pad 518. The second through electrode 519 may have a connection end 519d exposed from the back surface 511b of the first chip 512. The first chip 512 may include scribe lanes 513, and the second through electrodes may be arranged in the scribe lanes 513.

In this manner, a second chip pad 524 connected to the first dummy connection pad 516a may be connected externally via a second connection pad 526, a conductive bump 531, the first coupling pad 518 and/or the second through electrode 519.

In accordance with the example embodiments, a conductive bump may serve as a stub of a chip stack. Because the length of the stub corresponds to the height of the conductive bump, a length of the stub may be reduced, thus electrical loading of a semiconductor package may be reduced and signal integrity may be improved. Accordingly, the semiconductor package may operate at higher speed.

Although example embodiments have been described in detail hereinabove, it should be understood that many variations and/or modifications of the basic inventive concepts taught herein, which may appear to those skilled in the art, will still fall within the spirit and scope of the example embodiments as defined in the appended claims.

What is claimed is:

1. A chip stack comprising:
a first semiconductor chip;
a second semiconductor chip stacked on the first semiconductor chip,
each of the first and second semiconductor chips having
an active surface and a back surface opposite to the active surface; and
a plurality of connection pads arranged in a center of the active surface; and
at least one first through electrode formed in the first semiconductor chip and connected to at least one of the plurality of connection pads of the first semiconductor chip, a portion of the at least one first through electrode being exposed by the back surface of the first semiconductor chip,
wherein the active surface of the first semiconductor chip is arranged to face the active surface of the second semiconductor chip, and
wherein the plurality of connection pads of the first semiconductor chip are electrically connected to the plurality of connection pads of the second semiconductor chip.

2. The chip stack of claim 1, wherein the plurality of connection pads of the first and second semiconductor chips are arranged in the center of the active surface in a line.

3. The chip stack of claim 2, wherein the plurality of connection pads of the first and second semiconductor chips are a plurality of chip pads.

4. The chip stack of claim 2, wherein the each of the first and second semiconductor chips include a plurality of chip pads formed on the active surface, and the plurality of connection pads of the first and second semiconductor chips are a plurality of redistribution pads rerouted from the plurality of chip pads.

5. The chip stack of claim 1, wherein the first through electrode is formed through at least one of the plurality of connection pads of the first semiconductor chip.

6. The chip stack of claim 1, wherein the plurality of connection pads of the first semiconductor chip are electrically connected to the plurality of connection pads of the second semiconductor chip using conductive bumps.

7. The chip stack of claim 6, further comprising an adhesive layer interposed between the first semiconductor chip and the second semiconductor chip.

8. The chip stack of claim 1, further comprising a plurality of spacers arranged along the periphery between the first semiconductor chip and the second semiconductor chip.

9. The chip stack of claim 8, wherein at least one spacer connects a ground line or a power line of the first semiconductor chip to a ground line or a power line of the second semiconductor chip.

10. The chip stack of claim 1, further comprising a plurality of ball pads formed on the back surface of the first semiconductor chip having the at least one first through electrode, the plurality of ball pads being electrically connected to the exposed portion of the at least one first through electrode.

11. A semiconductor package comprising:
the chip stack of claim 10; and
a plurality of conductive bumps formed on the plurality of ball pads.

12. The chip stack of claim 4, further comprising:
a plurality of second coupling pads formed in a peripheral region of the active surface of the second semiconductor chip and electrically connected to the plurality of chip pads of the second semiconductor chip;
a plurality of first coupling pads formed on the active surface of the first semiconductor chip corresponding to the plurality of second coupling pads;
a plurality of coupling bumps electrically connecting the plurality of first coupling pads to the plurality of second coupling pads; and
at least one second through electrode extending through a peripheral region of the first semiconductor chip and being electrically connected to the at least one of the plurality of first coupling pads, the at least one second through electrode having a connection end exposed from the back surface of the first semiconductor chip.

13. The chip stack of claim 4, further comprising:
a plurality of first coupling pads formed in a peripheral region of the active surface of the first semiconductor chip and electrically connected to the plurality of the first connection pads; and
at least one second through electrode extending through a peripheral region of the first semiconductor chip and electrically connected to at least one of the plurality of first coupling pads, the at least one second through electrode having a connection end exposed from the back surface of the first semiconductor chip.

14. A semiconductor package including:
a chip stack of claim 1;
a wiring substrate having an upper surface on which the chip stack is mounted, and a lower surface, the wiring substrate being electrically connected to the at least one first through electrode of the chip stack;
a first encapsulant sealing the chip stack on the upper surface of the wiring substrate; and
external connection terminals formed on the lower surface of the wiring substrate and electrically connected to the exposed portion of the at least one first through electrode.

15. The package of claim 14, further comprising at least one connection bump interposed between the exposed portion of the at least one first through electrode and the wiring substrate.

16. The package of claim 14, wherein the wiring substrate has a central window through which the portion of the first through electrode is exposed, the semiconductor package further comprising bonding wires electrically connecting the wiring substrate to the exposed portion of the at least one first through electrode.

17. The package of claim 16, further comprising a second encapsulant sealing the window of the lower surface of the wiring substrate.

18. A method for manufacturing a chip stack, the method comprising:
preparing a first wafer including a plurality of first semiconductor chips, each of the first semiconductor chips having an active surface with a plurality of first connection pads;
preparing a second wafer including a plurality of second semiconductor chips, each of the second semiconductor chips having an active surface with a plurality of second connection pads corresponding to the plurality of first connection pads;
forming at least one first through electrode, the at least one first through electrode being connected to at least one of the plurality of first connection pads and extending through the first wafer;
stacking the second wafer on the first wafer so that the plurality of first connection pads are electrically connected to the corresponding plurality of second connection pads; and
dividing a stack of the first wafer and the second wafer into individual chip stacks.

19. The method of claim 18, further comprising backlapping the first wafer to expose a portion of the at least one first through electrode.

20. The method of claim 19, further comprising backlapping the second wafer.
